(19) United States
(12) Patent Application Publication
(10) Pub. No.: US 2013/0011574 A1
(43) Pub. Date: Jan. 10, 2013

(54) GRAPHENE PRODUCTION METHOD AND GRAPHENE PRODUCTION APPARATUS

(75) Inventors: Toshiyuki Kobayashi, Kanagawa (JP); Masashi Bando, Kanagawa (JP); Nozomi Kimura, Kanagawa (JP); Keisuke Shimizu, Kanagawa (JP); Koji Kadono, Tokyo (JP)

(73) Assignee: SONY CORPORATION, Tokyo (JP)

(21) Appl. No.: 13/531,068

(22) Filed: Jun. 22, 2012

(30) Foreign Application Priority Data
Jul. 6, 2011 (JP) 2011-149784

(51) Int. Cl. C23C 16/26; C23C 16/50; B82Y 40/00

(52) U.S. Cl. 427/535; 427/545; 118/723 R; 118/718; 977/843

(57) ABSTRACT

Provided is a graphene production method including: contacting a carbon source substance with a surface of a flexible film-forming target having electrical conductivity; and applying a current to the film-forming target and heating the film-forming target at a temperature exceeding a graphene production temperature to produce graphene from the carbon source substance on the surface of the film-forming target.

### CROSS REFERENCES TO RELATED APPLICATIONS

The present application claims priority to Japanese Priority Patent Application JP 2011-149784 filed in the Japan Patent Office on Jul. 6, 2011, the entire content of which is hereby incorporated by reference.

### BACKGROUND

The present application relates to a graphene production method and a graphene production apparatus; graphene being used as electronic materials, electrode materials or the like.

Graphene is a sheet-like substance where carbon atoms are arranged in a hexagonal grid structure, and is focused as electronic materials and electrode materials in recent years. Graphene is generally produced by chemical vapor deposition, i.e., by supplying a carbon source substance on a heated surface of a catalyst, and film-forming graphene on the surface of the catalyst.

For example, Japanese Unexamined Patent Application Publication No. 2009-107921, paragraph [0049], FIG. 1 discloses “A method of producing a graphene sheet” which includes heating a graphitizing catalyst laminated on a substrate, and supplying a carbon source substance to the catalyst to produce graphene. In the production method, a graphitizing catalyst is irradiated with electromagnetic waves such as a laser or infrared rays to heat the graphitizing catalyst.

Journal of Electronic Materials 39, 2190 (2010) discloses that graphene is produced by applying a current to a Ni thin film vapor-deposited on a Si/SiO₂ substrate, and supplying a carbon source substance on the Ni thin film, which is heated by resistive heating.

### SUMMARY

However, the method described in Japanese Unexamined Patent Application Publication No. 2009-107921, the electromagnetic wave irradiation is utilized to heat the graphitizing catalyst, which may be difficult to locally heat only the graphitizing catalyst. It is considered that other members of the graphene production apparatus are exposed to high temperature. Therefore, the production apparatus should be configured by a highly heat-resistant material or requires a cooling mechanism, which makes the production apparatus expensive. In addition, there are problems that it may take a long time to heat or cool the graphitizing catalyst and energy utilization efficiency is low.

In the method described in Journal of Electronic Materials 39, 2190 (2010), it requires a step of vapor-depositing a Ni thin film on the Si/SiO₂ substrate. In general, graphene is often transferred to other substrate (such as a transparent insulation member). Such transfer may be difficult. In addition, there are problems that a Si/SiO₂ substrate requiring high heat resistance (about 1000° C.) is expensive, the size of the Ni thin film (a site for producing graphene) is determined by the size of the substrate, and the like.

Thus, the graphene production methods described in Japanese Unexamined Patent Application Publication No. 2009-107921 and Journal of Electronic Materials 39, 2190 (2010) have a room for improvement, when graphene is mass produced industrially.

In view of the above-described circumstances, it is desired to provide a graphene production method and a graphene production apparatus that are suitable for mass production.

According to an embodiment of the present application, a graphene production method includes: contacting a carbon source substance with a surface of a flexible film-forming target having electrical conductivity; and applying a current to the film-forming target and heating the film-forming target at a temperature exceeding a graphene production temperature to produce graphene from the carbon source substance on the surface of the film-forming target.

The production method is to apply a current to the film-forming target, and the temperature of the film-forming target is increased by resistive heating. It is possible to prevent the members other than the film-forming target from reaching high temperature as compared with the case that the film-forming target is heated with electromagnetic irradiation. Therefore, there is no need to construct the production apparatus with a heat resistant material, and graphene can be produced at high energy efficiency. In addition, since the film-forming target is flexible, a large area film-forming target is readily available, which is suitable for mass production of graphene.

The film-forming target may include copper.

Using copper as the film-forming target, uniform monolayer graphene (having less defects and less multi-layered areas) can be produced due to catalytic activity and low carbon solid solubility, both of which are inherent properties of copper. On the other hand, copper has physical properties such as low emissivity (absorption), less absorption of electromagnetic waves, and low heat loss due to radiation, and may be difficult to heat with electromagnetic irradiation. However, the material having low heat loss due to radiation can be heated with less electric power, so that copper is heated efficiently by resistive heating according to the present application. In addition, copper is suitable as the film-forming target according to the present application in that copper has electrical conductivity suitable for resistive heating, has a high melting point, and is available at low costs.

The film-forming target may be a foil.

The foil can provide a larger surface area in respect to a section area, can provide high yields of graphene with respect to power consumption upon resistive heating, and can produce graphene at a lower applied current. When the film-forming target is a foil, it is possible to produce graphene on both surfaces of the foil. On the other hand, when the film-forming target is, for example, a catalyst metal laminated on the substrate, it is not possible to produce graphene on both surfaces.

The applying a current to the film-forming target and heating the film-forming target may include heating the film-forming target, while the film-forming target is carried by a roll-to-roll mechanism.

Since the film-forming target is flexible and has electrical conductivity according to the embodiment of the present application, it can be wound and carried by the roll-to-roll mechanism. In other words, it is possible to film-form graphene on the large area film-forming target in one production process, which is suitable for mass production of graphene.

The applying a current to the film-forming target and heating the film-forming target may include heating the film-forming target by auxiliary heating with electromagnetic irradiation.

Heating the film-forming target, which is heated by the resistive heating, with electromagnetic irradiation auxiliary enables a decrease of the current applied to the film-forming target, and shortens the time to increase the temperature of the film-forming target.

The contacting a carbon source substance with a surface of a flexible film-forming target may include contacting a plasmarized carbon source substance with the film-forming target.

When the plasmarized carbon source substance is used to produce graphene, plasma may have high temperature, so that the current applied to the film-forming target can be decreased and the film-forming speed of graphene can be increased.

A graphene production apparatus according to an embodiment of the present application includes a chamber, a first current terminal, a second current terminal and a power source.

The first current terminal is disposed within the chamber, and is contacted with a flexible film-forming target having electrical conductivity.

The second current terminal is disposed apart from the first current terminal within the chamber, and is contacted with the film-forming target.

The power source is configured to apply a current between the first current terminal and the second current terminal, and heat the film-forming target at a temperature exceeding a graphene production temperature to produce graphene from a carbon source substance on a surface of the film-forming target.

In such a configuration, a current can be applied to the film-forming target to heat the film-forming target by resistive heating. It prevents the members other than the film-forming target from reaching high temperature as compared with the case that the film-forming target is heated with electromagnetic irradiation. Therefore, the graphene production apparatus according to the present application can be composed of a material that is not a heat resistant material. In other words, graphene can be produced at low costs.

The graphene production apparatus may further include a roll-to-roll mechanism configured to carry the film-forming target while being brought into contact with the first current terminal and the second current terminal.

In such a configuration, the film-forming target can be carried by the roll-to-roll mechanism. It is possible to film-form graphene on the large area film-forming target in one production process.

The chamber may be a vacuum chamber. The roll-to-roll mechanism may be disposed within the vacuum chamber.

In such a configuration, the film-forming target is accommodated within the vacuum chamber during the carry by the roll-to-roll mechanism. It is therefore prevented oxygen and moisture from being entering into the vacuum chamber, and it is possible to produce high quality graphene.

The chamber may be a positive pressure chamber. The roll-to-roll mechanism may be disposed outside of the positive pressure chamber.

In such a configuration, the positive pressure chamber (chamber that can keep the positive pressure inside) can be used to configure the graphene production apparatus, and the vacuum chamber may not be used. It is therefore possible to decrease the production costs and the operating costs. Also, the positive pressure chamber can prevent oxygen and moisture from being entering into the chamber through the opening where the film-forming target, which is carried by the roll-to-roll mechanism, is introduced into the chamber.

Each of the first current terminal and the second current terminal may have a copper substrate coated with a graphene coating.

In such a configuration, high quality monolayer graphene can be formed because copper has catalytic activity and low carbon solid solubility, and can be intimately contacted with copper. It is possible to provide the current terminals having high electrical conductivity, small friction resistance, and high abrasion resistance. Thus, there can be provided the graphene production apparatus suitable for mass production of graphene. The first current terminal and the second current terminal may be rotated by a motor or not rotated.

As described above, it is possible to provide the graphene production method and the graphene production apparatus that are suitable for mass production.

These and other objects, features and advantages of the present disclosure will become more apparent in light of the following detailed description of best mode embodiments thereof, as illustrated in the accompanying drawings.

Additional features and advantages are described herein, and will be apparent from the following Detailed Description and the figures.

### BRIEF DESCRIPTION OF THE FIGURES

FIG. 1 is a schematic view of a graphene production apparatus according to a first embodiment of the present application;

FIG. 2 is a schematic view of a graphene production apparatus according to a second embodiment of the present application;

FIG. 3 is a schematic view of a graphene production apparatus according to a third embodiment of the present application;

FIG. 4 is a schematic view of a graphene production apparatus according to a fourth embodiment of the present application;

FIG. 5 is a schematic view of a current terminal according to the third and fourth embodiments of the present application; and

FIG. 6 is a graph showing measurement results of Raman spectroscopic analysis of graphene.

### DETAILED DESCRIPTION

Hereinafter, preferred embodiments of the present disclosure will be described in detail with reference to the appended drawings.

### First Embodiment

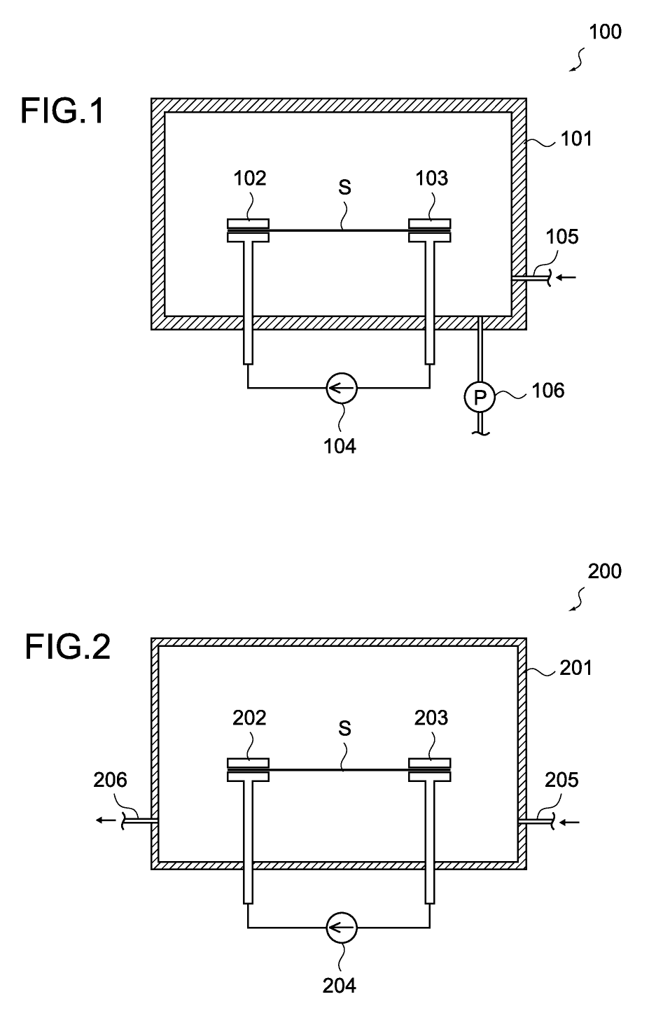

A first embodiment of the present application will be described. FIG. 1 is a schematic view of a graphene production apparatus 100 according to the first embodiment.

A graphene production apparatus 100 is an apparatus for producing graphene from a carbon source substance (a substance containing carbon atoms).

Graphene is a sheet-like substance having a hexagonal grid structure containing carbon atoms which are sp² bonded each other.

<Configuration of Graphene Production Apparatus>

As shown in FIG. 1, the graphene production apparatus 100 has a vacuum chamber 101, a first current terminal 102, a second current terminal 103, a power supply 104, a gas supply system 105 and a vacuum pump 106. A film-forming target S is set between the first current terminal 102 and the second current terminal 103. The first current terminal 102 and the second current terminal 103 are accommodated within the vacuum chamber 101, and are connected to the power supply 104, respectively. The gas supply system 105 and the vacuum pump 106 are connected to the vacuum chamber 101.

The vacuum chamber 101 keeps vacuum inside, and provides an atmosphere where graphene is produced. Since the vacuum chamber 101 is not required to have high heat resistance for the reason described later, the vacuum chamber having no heat resistance can be used.

The first current terminal 102 and the second current terminal 103 are disposed apart from each other within the chamber, and are contacted with the film-forming target S, respectively. The first current terminal 102 and the second current terminal 103 flow a current from the power supply 104 to the film-forming target S, and also support the film-forming target S in the first embodiment. The first current terminal 102 and the second current terminal 103 can pinch the film-forming target S, respectively. The film-forming target S is supported like a bridge by the first current terminal 102 and the second current terminal 103 within the chamber 101. In the graphene production apparatus 100, the film-forming target S may be supported only by the first current terminal 102 and the second current terminal 103, but also by a supporting member (guide). As the supporting member, a material having low thermal conductivity, high heat resistance and high insulation performance, for example, quartz or the like, is suitable.

The power supply 104 applies a current to the first current terminal 102 and the second current terminal 103. The power supply 104 may be DC or AC. A capacity of the power supply 104 is not especially limited. However, the greater capacity shortens the time to increase the temperature, which is suitable for mass production of graphene, as the film-forming target S is required to be heated to the predetermined temperature by resistive heating, as described later. For example, when the film-forming target S is a copper foil, a current density for heating it to 1000° C. is 10⁸ A/m². Then, the copper foil having a thickness of 8 μm and a width of 1 m is heated using a current of 800 A.

The gas supply system 105 supplies various gases into the vacuum chamber 101. Specifically, the gas supply system 105 supplies hydrogen gas for annealing the film-forming target S and a carbon source gas for producing graphene. The carbon source gas is a gas (gas phase under vacuum environment) including carbon-atom containing molecules, and can be, in particular, selected from methane, ethane, propane, butane, pentane, hexane, acetylene, ethylene, propylene, ethanol, butadiene, pentene, cyclopentadiene, cyclohexane, benzene, toluene and the like.

The graphene production apparatus 100 can have the above-described structure. In the graphene production apparatus 100, the film-forming target S is resistive heated. The parts other than the film-forming target S are not so heated to high temperature (e.g., 200° C. or less). Accordingly, the graphene production apparatus 100 can be made with the material selected not taking the heat resistance into consideration.

<Film-Forming Material>

The graphene produced according to the present application is formed a film on the film-forming target S. The film-forming target S has electrical conductivity, and can be flexible. As described later, according to the present application, a current is applied to the film-forming target S so as to resistive heat the film-forming target S. Therefore, the film-forming target S should have electrical conductivity.

The film-forming target S can be flexible, which leads to easy handling, and suitable for mass production of graphene. In particular, the flexible film-forming target S is desirable in that a roll-to-roll mechanism is applied.

Further, the film-forming target S is heated to the graphene production temperature (for example, 80° C., when copper is used) or more, and should be durable at that temperature. In addition, graphene is produced on the surface of the film-forming target S. So, the film-forming target S may be made with a material having catalytic activity to graphene.

The film-forming target S can be selected from a metal and an alloy. Specifically, the film-forming target S may be a pure metal such as copper (Cu), nickel (Ni), cobalt (Co), iron (Fe), platinum (Pt), palladium (Pd), ruthenium (Ru), iridium (Ir), gold (Au), silver (Ag), chromium (Cr), titanium (Ti), manganese (Mn), silicon (Si), gallium (Ga), indium (In) and aluminum (Al) or an alloy thereof.

Among the above-cited metals, copper is most desirable. This is because high quality “monolayer graphene” can be formed on the surface of copper, since copper has catalytic activity and low carbon solid solubility. The monolayer graphene has a single graphene sheet, i.e., has no two or more graphene sheets.

Graphene formed on the film-forming target S is transferred to, for example, a glass substrate and is used as a transparent electric conductive film or the like. If there is the area where the plural graphene sheets exist, the area has poor light transmission properties. Also, the plural graphene sheets have a weak interlayer bonding between the sheets, and are easily peeled to produce dusts. Copper has a chemical property to intimate contact with the graphene sheets and less solubilizes carbon. Therefore, the uniform monolayer graphene (less defects and less areas where the plural graphene sheets exist) can be provided.

In addition, copper has electrical conductivity suitable to resistive heating, has a high melting point, and is available at low costs as compared with other metals, and therefore is suitable to the film-forming target S.

The film-forming target S is described as flexible. Examples are metal “foil”, “wire”, “mesh” and the like. Among them, the foil is most suitable to the film-forming target S. This is because the foil not only can provide a large-area sheet-like graphene film, but also has a larger surface area in respect to a section area as well as high yields of graphene with respect to power consumption in the resistive heating. When the film-forming target S is a foil, it is possible to produce graphene on both surfaces of the foil. On the other hand, when the film-forming target is, for example, a catalyst metal laminated on the substrate, it is not possible to produce graphene on both surfaces.

As described above, the film-forming target S is desirably made with copper, and has a form of a foil. So, the “copper foil” is most desirable. The thickness, the width, the length or the like of the copper foil is not especially limited. From the standpoint of decreasing the power consumption of the resistive heating and the applied current, the copper foil is desirably thinner. However, when the copper foil is too thin, its strength may be decreased. It is desirable that the thickness be in the range from 1 μm to 100 μm, especially in the range from 5 μm to 50 μm.

<Graphene Production Method>

A graphene production method will be described using the graphene production apparatus 100. The graphene production method according to the first embodiment utilizes Low Pressure Chemical Vapor Deposition (CVD) to produce graphene under vacuum environment.

The film-forming target S is set within the vacuum chamber 101. As shown in FIG. 1, the film-forming target S is contacted with the first current terminal 102 and the second current terminal 103. For example, the film-forming target S is a copper foil having a thickness of 35 μm, a width of 15 mm and a length of 210 mm.

Then, the vacuum chamber 101 is evacuated using a vacuum pump 106. Thereafter, hydrogen gas is supplied to the vacuum chamber 101 through the gas supply system 105. The hydrogen gas can be supplied until a partial pressure thereof reaches 0.01 Torr. The partial pressure of hydrogen gas is not especially limited, but is desirably in the range of 10⁻⁴ Torr to 10 Torr.

The power supply 104 applies a current to the first current terminal 102 and the second current terminal 103. The applied current can be, for example, 40 A. The current flows through the film-forming target S between the first current terminal 102 and the second current terminal 103, and resistive heats the film-forming target S. Once the temperature of the film-forming target S reaches the predetermined temperature (for example, 1000° C.), it keeps for a predetermined time (for example, 5 minutes). The film-forming target S (oxidized in air) is reduced. The heating of the film-forming target S to be reduced is called “annealing”.

Then, graphene is produced on the film-forming target S. When the temperature of the film-forming target S exceeds the graphene production temperature upon annealing, graphene production is proceeded directly. When the temperature of the film-forming target S is lower than the graphene production temperature, the film-forming target S is heated to the graphene production temperature or more.

The heating temperature of the film-forming target S is desirably 400° C. or more, in particular 800° C. or more. When the film-forming target S is copper, the temperature range from 800° C. to 1084° C. (melting point of copper) is desirable.

Then, the carbon source gas is supplied to the vacuum chamber 101 through the gas supply system 105. For example, Methane as the carbon source gas can be supplied until a partial pressure thereof reaches 0.3 Torr. The partial pressure of methane gas is not especially limited, but is desirably in the range of 10⁻⁴ Torr to 10 Torr. When the carbon source gas supplied to the vacuum chamber 101 is contacted with the surface of the film-forming target S, the carbon source gas is degraded by heat. With catalytic activity of the film-forming target S, graphene is produced. The production of graphene lasts for, for example, 10 minutes.

After the application of current by the power source 104 and the supply of the carbon source gas are stopped, and the film-forming target S is cooled. It is thus possible to provide the film-forming target S on which graphene is produced.

In the above description, the carbon source gas is supplied to the vacuum chamber 101 after annealing, and graphene is then produced. However, hydrogen gas and the carbon source gas may be supplied to the vacuum chamber 101 before annealing. Since the reduction of the film-forming target S proceeds at lower temperature (for example, 300° C.) than the graphene production temperature, the film-forming target S is reduced in the course of increasing the temperature of the film-forming target S to graphene production temperature.

Graphene formed on the film-forming target S is transferred to a glass, quartz, a plastic or the like and can be then used as a transparent electric conductive film. When the film-forming target S is a copper foil, it is possible to provide high quality monolayer graphene as described above. As a result of analysis of graphene formed on the copper foil and transferred to the quartz, the light transmittance at a wavelength of 550 nm was 97%, and the sheet resistance was 200 Ω/sq.

The presence of graphene can be identified by measuring a mode of oscillation which is typical of graphene by Raman spectroscopic analysis. FIG. 6 is a graph showing the measurement results of Raman spectroscopic analysis of graphene. In the graph of FIG. 6, a peak at 2714 cm⁻¹ can be fitted by a single Lorenz function, which confirms the production of the monolayer graphene.

Thus, graphene can be produced. In the first embodiment, only the resistive heating is used to heat the film-forming target at a graphene production temperature or more, as described above. Accordingly, the parts other than the film-forming target (inner wall of the chamber 101 and the like) can be kept at relatively low temperature. Thus, the graphene production apparatus 100 can be made with the material selected not taking the heat resistance into consideration. Specifically, the graphene production apparatus 100 can be made with a relatively inexpensive material such as a glass, stainless steel and copper. That is, the costs of the graphene production apparatus 100 can be reduced.

Many substances have increased chemical reactivity, and therefore deteriorate under high temperature conditions. In the graphene production apparatus 100 according to the first embodiment, it is possible to prevent deterioration of the parts caused by heating. Thus, the graphene production apparatus has higher durability and lower maintenance frequency as compared with the graphene production apparatuses using other heating modes.

As the film-forming target, copper is suitable because copper has catalytic activity, as described above. However, copper has low emissivity (absorption) of around 0.03, that is difficult to absorb electromagnetic waves such as infrared rays, and has decreased heat loss due to radiation. It means that it is difficult to heat with electromagnetic irradiation and energy utilization efficiency is low. However, when copper is heated internally by resistive heating as in the first embodiment, the film-forming target can be heated to the predetermined temperature with less electric power just because copper has decreased heat loss due to radiation. In other words, the heating mode according to the first embodiment is suitable to heat copper.

In the case that the film-forming target is irradiated and heated with electromagnetic waves, the electromagnetic waves are absorbed by various components other than the film-forming target and are attenuated, or are reflected by the film-forming target. Thus, energy utilization efficiency may be low. In contrast, in the heating mode according to the first embodiment, the film-forming target can be heated efficiently to the predetermined temperature in a short time, so that takt time of a graphene production process can be shortened. Further, only the film-forming target is heated, so that a cooling time is correspondingly shortened. In this point, too, takt time can be shortened.

Furthermore, in the case that the film-forming target is irradiated and heated with electromagnetic waves, the film-forming target is not evenly heated by the positional relationship between the film-forming target and the irradiation source of the electromagnetic waves, and graphene may have low quality (many defects). In contrast, in the heating mode according to the first embodiment, the film-forming target can be heated evenly to prevent the quality of graphene from lowering caused by temperature distribution.

Energy of the resistive heating according to first embodiment is directly put into the film-forming target by applying a highly controllable current, so that in the heating mode according to the first embodiment, the temperature of the film-forming target can be controlled accurately at high speed. Especially when the film-forming target is copper, its heat capacity is low, which may provide remarkable advantages.

In the heating mode according to the first embodiment, the applied current can be feedback-controlled by the resistance value (which can be measured at the same time of applying the current) of the film-forming target while applying the current, since the resistance value of the metal is dependent upon the temperature.

### Second Embodiment

A second embodiment of the present application will be described. A description of the common features as the first embodiment will be omitted in the second embodiment. In the first embodiment, graphene is produced by the Low Pressure CVD. In the second embodiment, graphene is produced by an atmospheric pressure CVD.

FIG. 2 is a schematic view of a graphene production apparatus 200 according to the second embodiment. As shown in FIG. 2, the graphene production apparatus 200 has a chamber 201, a first current terminal 202, a second current terminal 203, a power supply 204, a gas supply system 205 and a gas emission part 206. A film-forming target S is set between the first current terminal 202 and the second current terminal 203. The first current terminal 202 and the second current terminal 203 are accommodated within the chamber 201, and are connected to the power supply 204, respectively. The gas supply system 205 and the gas emission part 206 are connected to the chamber 201.

The vacuum chamber 201 provides an atmosphere where the production of graphene is proceeded. Similar to the first embodiment, since the chamber 201 is not required to have high heat resistance, a commonly-used chamber can be used. Unlike the first embodiment, in the second embodiment, the chamber is not required to be the vacuum chamber. It is possible to use a chamber available at lower costs and having lower pressure resistance as compared with the vacuum chamber.

The first current terminal 202, the second current terminal 203 and the power supply 204 can be the same as described in the first embodiment. However, the heat of the film-forming target S is discharged by convection under atmospheric pressure environment. Therefore, the power source 204 is required to provide the first current terminal 202 and the second current terminal 203 with a current larger than that in the first embodiment (under vacuum environment).

The gas supply system 205 supplies various gases into the chamber 201. Specifically, the gas supply system 205 supplies an inert gas (argon, nitrogen or the like), hydrogen gas and a carbon source gas. The carbon source gas is a gas (gas phase under vacuum environment) including carbon-atom containing molecules, and can be, specifically, selected from methane, ethane, propane, butane, acetylene, ethylene and the like.

The graphene production apparatus 200 can have the above-described structure. In the graphene production apparatus 200, the film-forming target S is resistive heated. The parts other than the film-forming target S are not so heated to high temperature. Accordingly, the graphene production apparatus 200 can be made with the material selected not taking the heat resistance into consideration.

The film-forming target S set to the graphene production apparatus 200 can be flexible having electrical conductivity similar to that in the first embodiment. In particular, a copper foil is suitable.

<Graphene Production Method>

A graphene production method will be described using the graphene production apparatus 200. The graphene production method according to the second embodiment utilizes atmospheric pressure Chemical Vapor Deposition (CVD) to produce graphene under atmospheric pressure environment.

The film-forming target S is set within the chamber 201. As shown in FIG. 2, the film-forming target S is contacted with the first current terminal 202 and the second current terminal 203. For example, the film-forming target S is a copper foil having a thickness of 35 μm, a width of 15 mm and a length of 210 mm.

Then, the inert gas and hydrogen gas are supplied to the chamber 201 through the gas supply system 205. For example, a mixture gas of argon and hydrogen (3.9%) can be supplied. The concentration of hydrogen gas is not especially limited, but the range from 1 ppm to 4% is suitable. These gases can decrease an oxygen concentration and a moisture concentration within the chamber 201.

The power supply 204 applies a current to the first current terminal 202 and the second current terminal 203. The applied current can be, for example, 50 A. The current flows through the film-forming target S between the first current terminal 202 and the second current terminal 203, and resistive heats the film-forming target S. Once the temperature of the film-forming target S reaches the predetermined temperature (for example, 900° C.), it keeps for a predetermined time (for example, 5 minutes). The film-forming target S is reduced (annealed).

Then, graphene is produced on the film-forming target S. When the temperature of the film-forming target S exceeds the graphene production temperature upon annealing, graphene production is proceeded directly. When the temperature of the film-forming target S is lower than the graphene production temperature, the film-forming target S is heated to the graphene production temperature or more.

Then, the inert gas and the carbon source gas are supplied to the chamber 201 through the gas supply system 205. For example, a mixture gas of argon and methane (4%) can be supplied until a partial pressure of methane reaches 100 ppm. The concentration of methane gas is not especially limited, but is desirably in the range of 1 ppm to 5.3%.

When the carbon source gas supplied to the chamber 201 is contacted with the surface of the film-forming target S, the carbon source gas is degraded by heat. With catalytic activity of the film-forming target S, graphene is produced. The production of graphene lasts for, for example, 10 minutes.

After the application of current by the power source 204 and the supply of the carbon source gas are stopped, and the film-forming target S is cooled. It is thus possible to provide the film-forming target S on which graphene is produced.

In the above description, the inert gas and the carbon source gas are supplied to the chamber 201 after annealing, and graphene is then produced. However, hydrogen gas, the inert gas and the carbon source gas may be supplied to the chamber 201 before annealing. Since the reduction of the film-forming target S proceeds at lower temperature than the graphene production temperature, the film-forming target S is reduced in the course of increasing the temperature of the film-forming target S so as to produce graphene.

Thus, graphene can be produced. In the second embodiment, no equipment to provide the vacuum environment is required, and graphene can be mass produced at lower costs.

### Third Embodiment

A third embodiment of the present application will be described. A description of the common features as the first embodiment will be omitted in the third embodiment. In the third embodiment, graphene is produced by the Low Pressure CVD similar to the first embodiment. However, the third embodiment is different from the first embodiment in that a roll-to-roll mechanism is applied.

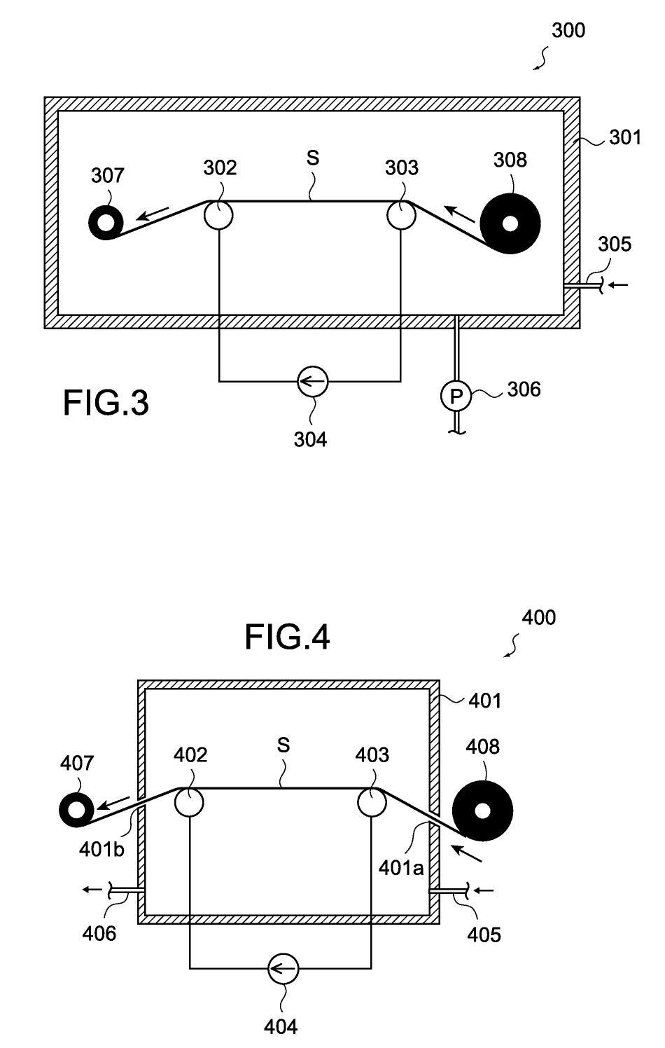

FIG. 3 is a schematic view of a graphene production apparatus 300 according to the third embodiment. As shown in FIG. 3, the graphene production apparatus 300 has a vacuum chamber 301, a first current terminal 302, a second current terminal 303, a power supply 304, a vacuum pump 306, a winding roll 307 and an unwinding roll 308. A film-forming target S is set on the winding roll 307 and the unwinding roll 308. The first current terminal 302, the second current terminal 303, the winding roll 307 and the unwinding roll 308 are accommodated within the vacuum chamber 301. The first current terminal 302 and the second current terminal 303 are connected to the power supply 304, respectively. The gas supply system 305 and the vacuum pump 306 are connected to the vacuum chamber 301.

The vacuum chamber 301, the power supply 304, the gas supply system 305 and the vacuum pump 306 can have the configurations similar to those of the first embodiment.

The film-forming target S set on the winding roll 307 and the unwinding roll 308 can be flexible having electrical conductivity similar to that in the first embodiment. In particular, a copper foil is suitable. The film-forming target S according to the third embodiment has a length that can be wound in a roll shape.

The winding roll 307 and the unwinding roll 308 form the roll-to-roll mechanism. Specifically, the rolled film-forming target S is set on the unwinding roll 308, and one end of the film-forming target S is connected to the winding roll 307. When the winding roll 307 rotates by rotative power, the film-forming target S is wound around the winding roll 307 and the unwinding roll 308 rotates corresponding to the rotation of the winding roll 307. Thus, the film-forming target S is carried from the unwinding roll 308 to the winding roll 307.

The first current terminal 302 and the second current terminal 303 are contacted with the film-forming target S, respectively. In the third embodiment, since the film-forming target S is carried by the above-mentioned roll-to-roll mechanism, the first current terminal 302 and the second current terminal 303 are required to be stably contacted with the moving film-forming target S.

Specifically, the first current terminal 302 and the second current terminal 303 are composed of an electrical conductive material, and may have arc shapes where the film-forming target S is contacted. Examples of the electrical conductive material are pure metals such as carbon, copper, stainless steel, titanium, tungsten, cobalt, nickel and platinum or an alloy thereof. The first current terminal 302 and the second current terminal 303 can be rotational rolls composed of the above-mentioned conductive materials. In addition, the first current terminal 302 and the second current terminal 303 having the following configuration may be highly desirable.

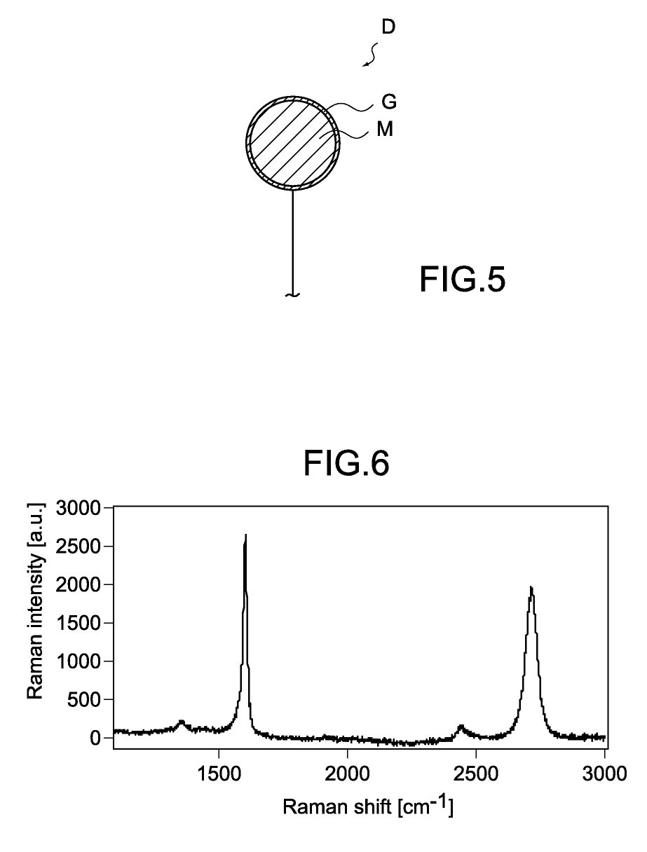

FIG. 5 is a sectional view of a current terminal D that can be used as the first current terminal 302 and the second current terminal 303. As shown in FIG. 5, in the current terminal D, the substrate M is coated with a coating G.

The substrate M can have a cylindrical shape or the arc shape where the film-forming target S is contacted. The substrate M can be copper, nickel, stainless steel and the like. For the following reason, copper is highly desirable. The coating G can be graphene. Graphene has high lubricating property and high electrical conductivity, and is therefore a desirable material for the current terminal that is slidably contacted with the film-forming target S.

As described above, when copper is coated with graphene, high quality monolayer graphene is formed by the copper catalytic activity and is intimately contacted with copper. When the substrate M is composed of copper, it is possible to provide the current terminal having high abrasion resistance against sliding on the film-forming target S. Copper is coated with graphene not only by the film-forming method according to the present application (CVD by resistive heating), but also by various methods.

Thus, when the first current terminal 302 and the second current terminal 303 have the structure where the substrate M composed of copper is coated with the coating G composed of the monolayer graphene (current terminal D), it is possible to provide the current terminals having high electrical conductivity, small friction resistance, and high abrasion resistance (that is, suitable for mass production of graphene).

The graphene production apparatus 300 can have the above-described structure. In the graphene production apparatus 300, the film-forming target S is resistive heated. The parts other than the film-forming target S are not so heated to high temperature. Accordingly, the graphene production apparatus 300 can be made with the material selected not taking the heat resistance into consideration.

<Graphene Production Method>

A graphene production method will be described using the graphene production apparatus 300. The graphene production method according to the third embodiment utilizes Low Pressure CVD (Chemical Vapor Deposition) to produce graphene under vacuum environment.

The rolled film-forming target S is set on the unwinding roll 308, and one end of the film-forming target S is connected to the winding roll 307. As shown in FIG. 3, the film-forming target S is contacted with the first current terminal 302 and the second current terminal 303. For example, the film-forming target S is a copper foil having a thickness of 35 μm and a width of 300 mm.

Then, the vacuum chamber 301 is evacuated using a vacuum pump 306. Thereafter, carbon source gas and hydrogen gas are supplied through the gas supply system 305. For example, the methane gas can be supplied until a methane partial pressure reaches 1 Torr, and the hydrogen gas can be supplied until a hydrogen partial pressure reaches 1 Torr. The partial pressures of methane gas and hydrogen gas are not especially limited, but are desirably in the range of 10⁻⁴ Torr to 10 Torr.

The power supply 304 applies a current to the first current terminal 302 and the second current terminal 303. The applied current can be, for example, 1000 A. The current flows through the film-forming target S between the first current terminal 302 and the second current terminal 303, and resistive heats the film-forming target S. By flowing the current, the area of the film-forming target S between the first current terminal 302 and the second current terminal 303 is resistive heated. When the temperature of the film-forming target S is increased, the film-forming target S is reduced (annealed) by the above-mentioned hydrogen gas.

When the temperature of the film-forming target S is further increased to the graphene production temperature, the carbon source gas is contacted with the surface of the film-forming target S and is degraded. With catalytic activity of the film-forming target S, graphene is produced on the area of the film-forming target S between the first current terminal 302 and the second current terminal 303.

Here, once the temperature of the film-forming target S reaches the graphene production temperature, the winding roll 307 is started to be rotated to start the roll-to-roll carry of the film-forming target S. For example, a winding tension can be 10N, and a carry speed can be 1 m/min.

Thus, the area of the film-forming target S between the first current terminal 302 and the second current terminal 303 are resistive heated to newly produce graphene. Thereafter, graphene is produced sequentially on the film-forming target S by the roll-to-roll carry. For example, when the film-forming target S is the copper foil and graphene is film-formed under the above-described conditions, it is possible to produce the monolayer graphene at a coverage of 95% or more.

If the film-forming target S is not well contacted with the first current terminal 302 and the second current terminal 303, the resistance is significantly increased. By collecting the log of the resistance values, the area of the film-forming target S that causes any problems upon film-forming can be specified later.

After the roll-to-roll carry of all of the film-forming target S is completed, the current application by the power source 304 and the carbon source gas supply are stopped, and the film-forming target S is then cooled. Once the film-forming target S leaves the heating zone, it is cooled sequentially. The film-forming target S wound around the winding roll 307 is not so heated to high temperature, which may not need to wait for cooling after the completion of the film-formation. Thus, the film-forming target S on which graphene is film-formed can be provided.

Thus, graphene can be produced. In the third embodiment, by the roll-to-roll carry, it is possible to produce graphene on the large area film-forming target S. In other words, it is possible to produce a large amount of graphene in one production process.

### Fourth Embodiment

A fourth embodiment of the present application will be described. A description of the common features as the second embodiment will be omitted in the fourth embodiment. In the fourth embodiment, graphene is produced by the atmospheric pressure CVD similar to the second embodiment. However, the fourth embodiment is different from the second embodiment in that a roll-to-roll mechanism is applied.

FIG. 4 is a schematic view of a graphene production apparatus 400 according to the third embodiment. As shown in FIG. 4, the graphene production apparatus 400 has a chamber 401, a first current terminal 402, a second current terminal 403, a power supply 404, a gas supply system 405, a vacuum pump 406, a gas emission part 406, a winding roll 407 and an unwinding roll 408. A film-forming target S is set on the winding roll 407 and the unwinding roll 408. The first current terminal 402 and the second current terminal 403 are connected to the power supply 404, respectively. The gas supply system 405 and the gas emission part 406 are connected to the chamber 401. The winding roll 407 and the unwinding roll 408 are disposed at external to the chamber 401.

The chamber 401 can be a positive pressure chamber capable of being a positive pressure (somewhat higher pressure than atmospheric pressure) within the chamber. The chamber 401 has an opening 401a and an opening 401b to communicate inside and outside of the chamber. The film-forming target S carried by the winding roll 407 and the unwinding roll 408 passes through the opening 401a and the opening 401b.

The power supply 404 and the gas supply system 405 can have the configurations similar to those of the second embodiment.

The film-forming target S set on the winding roll 407 and the unwinding roll 408 can be flexible having electrical conductivity similar to that in the second embodiment. In particular, a copper foil is suitable. The film-forming target S according to the fourth embodiment has a length that can be wound in a roll shape.

The winding roll 407 and the unwinding roll 408 form the roll-to-roll mechanism. Specifically, the rolled film-forming target S is set on the unwinding roll 408, and one end of the film-forming target S is connected to the winding roll 407. When the winding roll 407 rotates by rotative power, the film-forming target S is wound around the winding roll 407 and the unwinding roll 408 rotates corresponding to the rotation of the winding roll 407. Thus, the film-forming target S is carried from the unwinding roll 408 to the winding roll 407. The film-forming target S wound around the unwinding roll 408 passes through the opening 401a, enters into the chamber 401, passes through the opening 401b, gets out through the opening 401b from the chamber 401 and is wound around the winding roll 407.

The first current terminal 402 and the second current terminal 403 are contacted with the film-forming target S, respectively. The first current terminal 402 and the second current terminal 403 can be the current terminal D described in the third embodiment (see FIG. 5).

The graphene production apparatus 400 can have the above-described structure. In the graphene production apparatus 400, the film-forming target S is resistive heated. The parts other than the film-forming target S are not so heated to high temperature. Accordingly, the graphene production apparatus 400 can be made with the material selected not taking the heat resistance into consideration.

<Graphene Production Method>

A graphene production method will be described using the graphene production apparatus 400. The graphene production method according to the fourth embodiment utilizes the atmospheric pressure CVD.

The film-forming target S is set on the unwinding roll 408, and one end of the film-forming target S is connected to the winding roll 407 through the chamber 401. As shown in FIG. 4, the film-forming target S is contacted with the first current terminal 402 and the second current terminal 403. For example, the film-forming target S is a copper foil having a thickness of 35 μm and a width of 300 mm.

Then, an inert gas, hydrogen gas and carbon source gas are supplied through the gas supply system 405 into the chamber 401. For example, a mixture gas of argon, hydrogen and methane can be supplied. The concentration of methane gas desirably ranges from 1 ppm to 5.3%. The concentration of hydrogen gas desirably ranges from 1 ppm to 4%. These gases can decrease an oxygen concentration and a moisture concentration within the chamber 401. In the fourth embodiment, the flow rates of the supplied gases are controlled, and the chamber 401 can be a positive pressure chamber capable of being a somewhat higher pressure than atmospheric pressure (positive pressure) within the chamber 401. Thus, the supplied gases blow out from the opening 401a and the opening 401b, thereby preventing atmosphere from entering into the chamber 401.

The power supply 404 applies a current to the first current terminal 402 and the second current terminal 403. The applied current can be, for example, 1000 A. The current flows through the film-forming target S between the first current terminal 402 and the second current terminal 403. By flowing the current, the area of the film-forming target S between the first current terminal 402 and the second current terminal 403 is resistive heated. When the temperature of the film-forming target S is increased, the film-forming target S is reduced (annealed) by the above-mentioned hydrogen gas.

When the temperature of the film-forming target S is further increased to the graphene production temperature, the carbon source gas is contacted with the surface of the film-forming target S and is degraded. With catalytic activity of the film-forming target S, graphene is produced on the area of the film-forming target S between the first current terminal 402 and the second current terminal 403.

Here, once the temperature of the film-forming target S reaches the graphene production temperature, the winding roll 407 is started to be rotated to initiate the roll-to-roll carry of the film-forming target S. For example, a winding tension can be 10N, and a carry speed can be 1 m/min.

Thus, the area of the film-forming target S between the first current terminal 402 and the second current terminal 403 are resistive heated to newly produce graphene. Thereafter, graphene is produced sequentially on the film-forming target S by the roll-to-roll carry. For example, when the film-forming target S is copper, it is possible to produce the monolayer graphene uniformly by the catalytic activity of copper.

If the film-forming target S is not well contacted with the first current terminal 402 and the second current terminal 403, the resistance is significantly increased. By collecting the log of the resistance values, the area of the film-forming target S that causes any problems upon film-forming can be specified later.

Thus, graphene can be produced. In the fourth embodiment, by the roll-to-roll carry, it is possible to produce graphene on the large area film-forming target S. In addition, in the fourth embodiment, no equipment to provide the vacuum environment is required, and graphene can be mass produced at lower costs.

### Alternative Embodiment

The present application is not limited to the above-described respective embodiments, and can be changed without departing from the point thereof. Alternative embodiments of the above-described respective embodiments will be described below.

<Raw Material of Graphene>

In the first to fourth embodiments, the carbon source gas is supplied to the chamber as the raw material (the carbon source substance) of graphene. It is also possible to use a liquid or solid substance instead of supplying the carbon source gas. Even if the carbon source substance is liquid or solid, it may be used as long as it evaporates when the pressure of the chamber is decreased, or the temperature of the chamber is increased. For example, it is possible to dispose a container including the liquid or solid carbon source substance within the chamber.

Further, the polymer including carbon atoms laminated on the film-forming target in advance can be the carbon source substance. Examples of such polymer are poly(methyl methacrylate) and polystyrene. When the film-forming target S is heated, the polymer is degraded to provide the raw material of graphene.

<Current Terminal>

In the first and second embodiments, alternative members other than the first current terminal and the second current terminal can support the film-forming target S. In the third embodiment, the winding roll and the unwinding roll may be directly connected to the power source, and can be used as the first current terminal and the second current terminal. A plurality of current terminals may be used and a plurality of heating zones having different temperatures may be provided so that an annealing zone, a film-forming zone, a cooling zone, and the like may be formed.

<Plasmarization of Carbon Source Gas>

In the first and third embodiments, the carbon source gas supplied to the vacuum chamber can be plasmarized to provide the raw material of graphene. For example, a high frequency electrode may be disposed in parallel to the film-forming target, a high frequency voltage may be applied to the carbon source gas, which may be plasmarized. Plasma of the carbon source gas may have high temperature, so that the current applied to the film-forming target can be reduced and the film-forming speed of graphene can be increased. The graphene film-forming conditions are as follows: for example, a frequency of 13.56 MHz, power of 500 W, a methane gas pressure of 0.1 Torr.

<Auxiliary Heating>

In the first to fourth embodiments, the film-forming target is resistive heated. In addition, it may be auxiliary heated with electromagnetic irradiation (radiation, laser irradiation, lamp irradiation and the like). In particular, infrared rays heating by a ceramic heater or a halogen lamp are effective. This will enable to reduce the current applied to the film-forming target, and shorten the time to increase the temperature of the film-forming target. For example, when the film-forming target is the copper foil, a parallel plate type ceramic heater is disposed at top and bottom of the copper foil, and is heated to 500° C. Then, the current to heat the film-forming target to 1000° C. may be decreased from 40 A to 35 A. In addition, the time to heat the film-forming target to 900° C. may be shorten from 8 seconds to 7 seconds.

The present application may have the following configurations.
(1) A graphene production method including:

contacting a carbon source substance with a surface of a flexible film-forming target having electrical conductivity; and

applying a current to the film-forming target and heating the film-forming target at a temperature exceeding a graphene production temperature to produce graphene from the carbon source substance on the surface of the film-forming target.
(2) The graphene production method according to (1) above, in which the film-forming target includes copper.
(3) The graphene production method according to (1) or (2) above, in which the film-forming target is a foil.
(4) The graphene production method according to any one of (1) to (3) above, in which

the applying a current to the film-forming target and heating the film-forming target includes heating the film-forming target, while the film-forming target is carried by a roll-to-roll mechanism.
(5) The graphene production method according to any one of (1) to (4) above, in which

the applying a current to the film-forming target and heating the film-forming target includes heating the film-forming target by auxiliary heating with electromagnetic irradiation.
(6) The graphene production method according to any one of (1) to (5) above, in which

the contacting a carbon source substance with a surface of a flexible film-forming target includes contacting a plasmarized carbon source substance with the film-forming target.
(7) A graphene production apparatus, including:

a chamber;

a first current terminal disposed within the chamber and contacted with a flexible film-forming target having electrical conductivity;

a second current terminal disposed apart from the first current terminal within the chamber, and contacted with the film-forming target; and

a power source configured to apply a current between the first current terminal and the second current terminal, and heat the film-forming target at a temperature exceeding a graphene production temperature to produce graphene from a carbon source substance on a surface of the film-forming target.
(8) The graphene production apparatus according to (7) above, further including

a roll-to-roll mechanism configured to carry the film-forming target while being brought into contact with the first current terminal and the second current terminal.
(9) The graphene production apparatus according to (7) or (8) above, in which

the chamber is a vacuum chamber; and

the roll-to-roll mechanism is disposed within the vacuum chamber.
(10) The graphene production apparatus according to any one of (7) to (9) above, in which

the chamber is a positive pressure chamber; and

the roll-to-roll mechanism is disposed outside the positive pressure chamber.
(11) The graphene production apparatus according to any one of (7) to (10), in which

each of the first current terminal and the second current terminal has a copper substrate coated with a graphene coating.

It should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claims.

The invention is claimed as follows:

1. A graphene production method comprising:
contacting a carbon source substance with a surface of a flexible film-forming target having electrical conductivity; and
applying a current to the film-forming target and heating the film-forming target at a temperature exceeding a graphene production temperature to produce graphene from the carbon source substance on the surface of the film-forming target.

2. The graphene production method according to claim 1, wherein
the film-forming target includes copper.

3. The graphene production method according to claim 1, wherein
the film-forming target is a foil.

4. The graphene production method according to claim 1, wherein
the applying a current to the film-forming target and heating the film-forming target includes heating the film-forming target, while the film-forming target is carried by a roll-to-roll mechanism.

5. The graphene production method according to claim 1, wherein
the applying a current to the film-forming target and heating the film-forming target includes heating the film-forming target by auxiliary heating with electromagnetic irradiation.

6. The graphene production method according to claim 1, wherein
the contacting a carbon source substance with a surface of a flexible film-forming target includes contacting a plasmarized carbon source substance with the film-forming target.

7. A graphene production apparatus, comprising:
a chamber;
a first current terminal disposed within the chamber and contacted with a flexible film-forming target having electrical conductivity;
a second current terminal disposed apart from the first current terminal within the chamber, and contacted with the film-forming target; and
a power source configured to apply a current between the first current terminal and the second current terminal, and heat the film-forming target at a temperature exceeding a graphene production temperature to produce graphene from a carbon source substance on a surface of the film-forming target.

8. The graphene production apparatus according to claim 7, further including
a roll-to-roll mechanism configured to carry the film-forming target while being brought into contact with the first current terminal and the second current terminal.

9. The graphene production apparatus according to claim 8, wherein
the chamber is a vacuum chamber; and
the roll-to-roll mechanism is disposed within the vacuum chamber.

10. The graphene production apparatus according to claim 8, wherein
the chamber is a positive pressure chamber; and
the roll-to-roll mechanism is disposed outside the positive pressure chamber.

11. The graphene production apparatus according to claim 8, wherein
each of the first current terminal and the second current terminal has a copper substrate coated with a graphene coating.
